(19) United States
(12) Patent Application Publication
(10) Pub. No.: US 2014/0087546 A1
(43) Pub. Date: Mar. 27, 2014

(54) Method and device for coating substrates

(71) Applicants: Michael Harr, Kelkheim (DE); Hilmar Richter, Niddatal (DE); Stefan Bossert, Zwickau (DE); Ralf Steudten, Zwoenitz (DE); Steffen George, Dennheritz (DE); Sebastian Tittel, Zschorlau (DE); Werner Schade, Neukirchen-Adorf (DE)

(72) Inventors: Michael Harr, Kelkheim (DE); Hilmar Richter, Niddatal (DE); Stefan Bossert, Zwickau (DE); Ralf Steudten, Zwoenitz (DE); Steffen George, Dennheritz (DE); Sebastian Tittel, Zschorlau (DE); Werner Schade, Neukirchen-Adorf (DE)

(73) Assignee: CTF SOLAR GMBH, Dresden (DE)

(21) Appl. No.: 14/000,709

(22) PCT Filed: Feb. 20, 2012
(86) PCT No.: PCT/EP12/52860

§ 371 Date: Nov. 23, 2013

(30) Foreign Application Priority Data
Feb. 21, 2011 (DE) 10 2011 004 441.8

(51) Int. Cl. H01L 31/18; C23C 16/46

(52) U.S. Cl. CPC H01L 31/18; C23C 16/46; H01L 31/1828; H01L 31/1892
USPC 438/478; 118/725

(57) ABSTRACT

The invention relates to a method and device for coating plate-shaped substrates, in particular glass substrates for solar cell production. The method includes heating the substrates, which are moved on transporting shafts through heating and coating chambers, by a different amount on the upper and lower sides, so that the coating temperature can be increased without the substrates becoming too soft to handle. A device is described which is suitable for carrying out the method and has heating and coating chambers, which have independent heating systems, as well as a transport system.

The invention relates to a method and a device for coating plate-shaped substrates, in particular glass substrates for solar cell production.

In the future of energy generation, solar cells will play a crucial role. in this area, in particular thin-film solar cells have advantages due to a more economic use of resources, and their suitability for mass production. As an alternative to solar cells based on silicon, especially thin-film solar cells based on cadmium telluride (CdTe) are very suitable. CdTe has an energy gap of 1.45 eV which makes it well suitable for absorbing sunlight. CdTe thin-film solar cells therefore have a high electric efficiency. Usually, CdTe is used in a layered structure together with cadmium sulfide (CdS), to create the necessary pn-transition consisting of a double layer of p-CdTe-n-CdS. CdS functions here, as it were, like a window, absorbing only a small part of the visible light, while the remainder may penetrate to the CdTe, where finally the charge carriers resulting in the photo voltage are created.

The substrate used in producing thin-film solar cells based on CdTe is usually glass. Starting with the substrate, subsequently the front contact is deposited, followed by the n-CdS-layer, the p-CdTe-layer and finally the back contact. A transparent, conductive oxide (TCO) serves as the front contact; usually indium-doped tin oxide (ITO) is used. Other well-known TCOs include fluorine-doped tin oxide (FTO) and aluminium-doped zinc oxide (AZO). In the following, the production of the front contact is not described further.

As the back contact a metal layer is used, whereby additional layers may be added partially to the CdTe layer to increase stability of the solar cell, and to ensure ohmic adjustment.

When in the following description the term substrate is used, this is understood to mean that the preparatory process steps required on the substrate, such as depositing the front contact, cleaning and polishing etc., are completed.

When the temperature of the substrate is mentioned, the surface temperature of the underside, i. e. the downwards-facing side usually provided with a TCO film, is meant. This temperature is measured contactlessly by sensors, just like the temperature of the upper side. The expert knows that these data, and further data generated by the device, are transmitted individually or together with the data of upstream or downstream devices to one or more data processing units which regulate the individual systems based on these data, while taking into account the overall process. The method according to the invention is also controlled in such a manner.

In particular the Close-Spaced-Sublimation (CSS) method has proven suitable for depositing CdS and CdTe. In this method, the base materials, for example CdTe granules of high purity are heated in a container, particularly in a vaporization crucible suitable for this purpose, up to a temperature to circa 600 to 770° C., in order to sublimate, or vaporize, the material to be deposited on the substrate, whereby the substrate passes over the source at close distance. The distance between the source of the film material and the substrate ranges here from only a few millimetres to a few centimetres. For heating the vaporization crucibles, for example resistance heating elements or IR-radiation elements may be used. Deposition usually takes place in a vacuum chamber at a residual gas pressure of 10⁻⁴ to 10 mbar, whereby before this, purging with an inert gas such as nitrogen or argon may take place. The substrate itself typically has a temperature ranging from 480 to 550° C., if common soda-lime glass is used. The glass substrate reaches this temperature during the transport process when it passes through one or more heating chambers before entering the deposition chamber proper, where deposition takes place. In principle, a high substrate temperature is desirable for attaining a high efficiency, as observations have shown that below a substrate temperature of 575° C. the efficiency decreases significantly. However, at very high substrate temperatures only equally expensive temperature-resistant glass substrates may be used. On the whole, this method is characterized by high deposition rates of several μm/min.

The movement of the substrate through the heating and/or vaporization chambers is effected using transport systems based on castors arranged on shafts. A transport system using continuous conveying shafts for solar cells made of silicon may also be gathered from publication WO 03/054975 A2. However, this does not have additional castors arranged on the conveying shafts, so that the entire surface of the comparably small solar cells rests on the conveying shafts. Conveying shafts of this kind are used in a furnace during a heat treatment process. For producing solar cells with large surfaces by means of depositing vaporized material on their underside, such conveying shafts are unsuitable, since in this case the substrate side on which deposition is to take place, or has taken place, would be touching the shafts with its entire surface, thus damaging the film on its whole surface.

The substrate is plate-shaped and has in prior art a typical distance between supports of 600 mm crosswise to the direction of transport, and is moved only on outer castors. Greater widths are not suitable for this process if common soda lime glass is used. As substrate, glass is used preferably. Glass is often regarded as a fluid which at room temperature has a particularly high viscosity. For this reason it is not possible to state an exact melting temperature, but its viscosity decreases as the temperature increases. To describe the softening of glass, various temperature points are used, the values of which are defined via the exponent of dynamic viscosity (common logarithm).

In the following, the transformation point Tg, which has a viscosity exponent of 12.0, is used. The transformation point lies within the transformation range with an exponent range of 12.0 to 13.4. The Tg value of the glass used is in the range of 550 to 555° C. (typical values for float glass are in the range from 540 to 560° C.). The transformation temperature marks the temperature value at which the substrate's dynamic viscosity reaches the transformation point. In the following, the range of the transformation temperature (transformation temperature range) describes a temperature range in which the viscosity exponent ranges from 12.0 to 13.4.

At high process temperatures near the transformation temperature (at circa 540 to 560° C., depending on the variety of glass), a plastic deformation due to the viscous flow of glass arises, which is irreversible and should be kept to a minimum. The low transformation temperature of the glass is also the reason why the substrate, if it is moved on outer castors only, at present cannot be provided with deposits at higher temperatures than circa 520° C.

Taking the prior art described above as point of departure, the object is therefore to present a method and a device for depositing glass substrates of nearly any width, using the CSS-method at temperatures in the range of the transformation temperature.

According to the invention, the object is solved in that the method according to claim 1 is used. Advantageously, this method is carried out in a device according to claim Error! Reference could not be found. Advantageous embodiments of method and device are described in the corresponding dependent claims.

### Method

According to the invention, the substrate is heated in a heating chamber or in several subsequent heating chambers until reaching the range of the substrate's transformation temperature. In parallel to, or subsequent to, heating the substrate up to transformation temperature, the upper side of the substrate is heated to a lower temperature than its underside, whereby the substrate is made to bulge, which ensures easier manageability of the substrate even at temperatures above the transformation temperature. The correspondingly heated substrate is provided with a film. Among the preferable materials to be deposited CdS and/or CdTe are used, however the materials copper, indium and gallium are also possible for CIS- or CIGS-solar modules, and the materials copper, zinc, tin and sulphur for CZTS-solar modules

During deposition according to the CSS-method, the substrate is placed, as described, above the depositing material container. Therefore, a supporting device for the substrate cannot be placed in direct vertical position above the depositing material container, as this would interfere with the deposition and would itself be exposed to undesired deposition. In this position the substrate, since it has a temperature above the transformation temperature, would be sagging too much, which would result in an uneven coating.

According to the invention, this is avoided by heating the underside of the substrate up to a higher temperature than the upper side. Thereby, the hotter underside of the substrate advantageously expands more than the upper side, thus creating an inner tension within the substrate that counteracts any sagging.

Preferably the substrate is shaped rectangular. In a further preferred embodiment the substrate is shaped as a square. When using several supports for the substrate, in front of and behind a depositing material container, the downward bulge of the substrate is prevented, and the attainable distance between supports is sufficient to bridge the container width with a tolerable amount of sagging.

The transformation temperature of the substrate is dependent on the material used. Preferably, common lime soda glass is used as a substrate, the transformation temperature of which ranges from 540° C. to 560° C.

The temperature of the underside of the lime soda glass substrate is higher than 520° C. during deposition, ranging preferably between 540° C. and 570° C., and especially preferably it is circa 550° C.

The temperature difference between underside and upper side of the lime soda glass substrate is preferably at least 2K to 4K, further preferably 5K to 8K and especially preferably circa 6K. Research conducted on lime soda glass substrates has shown that under typical process conditions (process duration 10 minutes, process temperature 550° C., glass thickness circa 3.2 mm) the deformations of the glass substrate do not exceed tolerable levels, provided the distance between supports is not higher than circa 300 mm to 400 mm, preferably 350 mm.

This advantageous process method allows it to complete process steps, which must be performed at temperatures in the range of the transformation temperature, before a temperature equalization has been reached between both sides of the substrate due to heat conduction.

After the depositing process the substrate is slowly cooled down. This is necessary to avoid tensions within the substrate. The adherence of the deposited layers to the substrate is not affected by slow cooling.

In a preferred embodiment the average substrate temperature during depositing a layer is in the range of the transformation temperature of the substrate, having regard to the temperature difference between upper- and underside of the substrate according to the invention, and said average substrate temperature is cooled down, after depositing the layer, below the range of the transformation temperature. Subsequently it is heated again, re-establishing the temperature difference between upper- and underside according to the invention. This is followed by another process step in depositing.

During depositing, the substrate passes over containers with the material to be deposited. These containers have a higher temperature than that of the underside of the substrate. Due to heat conduction within the substrate, the whole substrate heats up, though more slowly, including its backside. This would result in a lower tension within the substrate. However, to be able to maintain the temperature difference according to the invention, the substrate requires cooling down between these containers. Therefore a temperature gradient in the substrate is created on purpose, so that the substrate's underside is kept at the process temperature necessary for depositing the film, but overheating is avoided. This is achieved by the device of the heating system according to the invention including the inner chambers (tunnels), and by controlling respectively regulating them. The settings of the heating system are dependent on the heat conduction of the substrate from its underside towards its upper side. Preferably, the containers are arranged in pairs after one another, with a large distance between the paired containers. This large distance preferably amounts to circa 385 mm. If the distance between the containers is bigger, cooling down the substrate below the transformation temperature is possible. Before the next process step in depositing, the average substrate temperature needs to be brought to transformation temperature again by the heating process according to the invention. This approach avoids that, accompanied by a temperature equalization between upper and underside, the bulge and correspondingly the manageability of the substrate would be lost. This manageability is ensured by the intervening cooling and re-heating.

During the process transport systems are used in which the substrate rests on castors. In those parts of the substrate which rest on the castors, damages to the areas of deposition will occur: Film deposition in these areas is not complete, or the layer sequence damaged due to mechanical action. As such areas interfere with the proper functioning of the solar cell they need to be eliminated. This is done either by removing the faulty film, or the damaged deposition areas in these areas advantageously by mechanical scratching, laser ablation, sand blasting or grinding (abrasion) from the substrate, or by separating and thus isolating the damaged from the undamaged areas, which is preferably achieved by laser ablation.

In order to perform the method according to the invention, the substrate is preferably moved through one or several heating chambers of which each has a higher temperature than the preceding one, until the temperature required for depositing the film is reached. Up to that range in which the substrate exceeds the transformation temperature, i.e. under 540° C., it is advantageously moved along on conveying shafts having two outer castors and few inner castors (preferably having one inner castor at a substrate width of 1200 mm). Inner castors here means castors supporting the substrate, which are arranged between two outer castors on a common shaft with these. At the latest in the last chamber before deposition, the substrate reaches the range of the transformation temperature, and here the shafts of the transport system preferably include further inner castors (preferably three inner castors in total at a substrate width of 1200 mm). The shafts in the area where the underside temperature of the substrate is lower than transformation temperature, thus have their first inner castor placed between both outer castors, with the inner castor preferably arranged nearly centrally between both outer castors; and the shafts in the area where the underside temperature of the substrate reaches transformation temperature, have at least one further inner castor. The further inner castors are preferably arranged approximately halfway between the nearly centred inner castor and the outer castors. Upper and underside of the substrate are heated up to different temperatures using heating systems for the upper- and underside. This is preferably done by means of separate control (i. e. regulation) of the respective heating systems for the upper- and underside. The temperatures on the upper- and underside are preferably controlled by sensors (preferably non-contact measurement pyrometers). The substrate bulges slightly, and may therefore bridge the greater distance between the shafts shock-free when passing from the heating chamber into the subsequent deposition chamber, and it may be placed in the deposition chamber without any additional support device above the depositing material containers.

This method is preferably used to produce CdS/CdTe thin-film solar cells.

During film deposition, the distance between the substrate and the containers, from which the material to be deposited is sublimated/evaporated, is preferably circa 3 mm to 50 mm, especially preferably 5 mm to 20 mm. The distance should be kept as small as possible in the CSS-method. In prior art, distances of under 5 mm have also been described. In these cases, first a CdS layer and afterwards a CdTe layer are deposited. Accordingly, the substrate is first moved over vaporization crucibles containing CdS, and subsequently over vaporization crucibles containing CdTe. Deposition with these two materials therefore takes place directly after one another within one process.

In a further preferred embodiment, the deposition with CdS takes place within a deposition chamber and that with CdTe subsequently in a second deposition chamber. In an equally preferred embodiment the substrate is cooled down between the two deposition steps. This intermediate cooling takes place in one or more heating chambers arranged between the deposition chambers. Advantageously, by separating the two deposition steps, a higher throughput speed is made possible, whereby the intermediate cooling process step ensures that the substrate does not soften too much, and that by renewed heating its stabilizing bulge may be restored in the manner described.

Finally the substrates pass through one or several heating chambers, which function as cooling zone. In this zone they may preferably be cooled slowly at first, and once a temperature range between circa 400° C. and 500° C. is reached—depending on the glass variety used—they may be cooled more quickly.

As already detailed above when describing the prior art, film deposition preferably takes place in a vacuum, however in principle film deposition may also take place at higher pressure, up to and including standard pressure.

The method according to the invention is preferably used for film deposition on substrates having a greater width crosswise to the transport direction than the usual substrates of 600 mm width. Accordingly, plate-shaped substrates with a width of >700 mm, preferably of >1000 mm, and especially preferably with a width of circa 1200 are suitable. In principle however, film deposition on substrates of nearly any desired width is feasible, provided the distance between two supporting castors does not exceed the acceptable measurements regarding the selected process temperature and substrate material.

### Device

The device according to the invention comprises at least one heating chamber executed as a vacuum chamber having at least two heating systems, which may be controlled (or regulated) independently of each other, in an inner chamber. At least one heating system heats the upper side of the substrate, and at least one heating system heats its underside. Each heating system has one or more heating elements. The heating systems are set in such a manner that the underside of the substrate has a higher temperature than the upper side. Moreover, the device has at least one heating chamber, likewise executed as a vacuum chamber, and a deposition chamber positioned downstream in transport direction, as well as one transport system for the substrate, which extends through the heating chamber, and one transport system for the substrate which extends through the deposition chamber. Both transport systems have several, parallel, axially spaced apart shafts arranged one after another in transport direction, and vertically with respect to this transport direction. The transport speed of the substrate in the transport systems is preferably between 0.5 m/s and 5 m/s, particularly preferably between 1 m/s and 4 m/s, and further particularly preferably between 1.5 m/s and 3 m/s.

The heating chamber executed as a vacuum chamber has an inner chamber which is advantageously spaced apart from the inner wall of the heating chamber. The outside of the inner chamber is preferably provided with a temperature insulation. In inward direction, the heating systems and the wall of the inner chamber follow. That means, the heating systems are arranged between the insulation material and the inner wall. This serves to attain thermal equipartition of the heat emission from the heating system, since the inner wall of the inner chamber forms a tunnel, which distributes the heat emitted by the heating systems diffusely onto the substrate and acts as an indirect heater on the substrate. By means of the thermal insulation, direct radiation of the heat originating in the heating system onto the wall of the inner chamber is prevented. A transport system extends throughout the inner chamber and the entire heating chamber. This system comprises a number of shafts to effect movement of the substrate, which shafts pass through the wall and are arranged outside the inner chamber.

As material for the inner wall of the inner chamber, preferably a metal is used, such as for example molybdenum (or a molybdenum alloy). In further preferred embodiments quartz or a carbon composite material are intended for use.

The surface temperature on the underside of the substrate is preferably measured contactless via sensors. In a preferred embodiment, the sensors are arranged outside the heating chamber and measure the temperature values of the substrate via small holes, which spread through the whole construction. The heating system may be controlled advantageously. The data taken by the temperature sensors and other information regarding the device (such as feed rate and substrate position) are also recorded, preferably by sensors, and transmitted to a central data processing unit which controls the device and is not described in detail here. The heating system includes one or several heating coils, which are preferably executed as a resistance heating. In this case, the heating coils are arranged between the shafts individually or in groups, in loops, zigzags, in a meandering shape, or in any other form of laying known from prior art. The temperature of each heating coil in this group of heating coils may be controlled individually. Below and above the heating system, reflexion sheets (reflecting surfaces) are arranged, and preferably these have a laterally angled projection which reflect the emitted heat towards the substrate. Due to the lateral projection, the lateral edge of the substrate is heated, too. The heating systems are preferably arranged between the reflecting surfaces and the inner wall of the inner chamber. At least the reflecting surfaces on the outer edges in parallel to the transport direction preferably have projections laterally angled towards the substrate in such a way as to heat the lateral surfaces of the substrate as well.

Only by arranging the heating systems and inner chamber according to the invention and by purposeful control of the heating systems it is possible to apply a film to the underside of the substrate and to maintain the required process temperature at the underside of the glass by a heating to a lesser degree, or even by cooling the upper side of the glass. To this end, the heating systems for the upper side preferably generate a temperature lower by circa 10K than the heating systems for the underside.

The shafts of the transport system are arranged one after another and axially spaced apart in transport direction, and arranged vertically to the transport direction. The shafts are here arranged horizontally, whereby preferably in transport direction their arrangement should have no or only a very low gradient (preferably <3%).

The shafts are preferably led out of the inner chamber via feed-through ducts and are mounted outside that chamber. The shaft drive, too, is preferably arranged outside the heated inner chamber, but within the vacuum. The drive operates preferably via a direct mechanical connection to the shaft, for example by means of an engine, whose gear, or chain drive, directly acts on at least one shaft end. In the inner chamber, between the feed-through ducts, and closely spaced apart from them, for each shaft two outer castors are arranged. Between the outer castors there is at least one inner castor each arranged. For the substrate, the outer castors preferably have conical contact areas, whose diameter increases towards the nearest shaft end. The outer castors are preferably provided with angled collars. The shafts on which the substrate's underside temperature exceeds its transformation temperature are preferably provided with two or more inner castors. Preferably, the outer castors of these shafts have a greater distance of the collars than those shafts for which the substrate's underside temperature is lower than its transformation temperature.

Since the substrate is transported on a plurality of castors, it is necessary to prevent the front edge—in transport direction—of the plate-shaped substrate from sagging on reaching the next castor, and from exposing it to shock on moving it to the next shaft, as this could result in damage to the edge. This phenomenon might be addressed by reducing the distances between the shafts. However, a problem arising in this case is that the then available space between two shafts is no longer sufficient to accommodate the necessary fittings, such as for example the vaporization crucibles. When the substrate is transferred from one chamber to another it is also necessary to bridge a greater distance between the shafts without marked sagging of the substrate's front edge.

To solve this problem, by suitable controlling (regulating) of the heating systems the underside of the substrate is heated more than the upper side. Even small temperature differences between upper and underside lead to an elastic bending of the substrate due to the resulting different thermal expansion of both sides. This causes the edges of the substrate to be in a higher position than its centre. At the same time, the substrate is subject to gravity. When the substrate rests on outer castors, which are merely arranged on the edges, gravity causes the substrate to bend, which bending points to the same direction as bending due to heat. Thus both processes reinforce each other. However, if in addition to the outer castors supporting the substrate on the edge, a support in the centre of the disc by means of one or more inner castors is added, support of the disc on the inner castors results in an at least partial compensation of the thermally caused upward bending of the substrate edges by the downward pull of gravity, so that the resulting total bending decreases.

The deposition chamber is also executed as a vacuum chamber and is provided with an inner chamber for thermal equipartition. The transport system, which extends throughout the entire deposition chamber, takes over the substrate discs from the transport system of the upstream heating or deposition chamber and transfers it to the transport system of the downstream heating or deposition chamber. During transport through the inner chamber, the substrate discs are provided with a film on their underside. The materials to be deposited (preferably CdS or CdTe) are arranged in heated containers open at the top (vaporization crucibles) above which the substrate passes at close distance. Directly above these containers, advantageously no transport castors are arranged to prevent or reduce as far as possible any undesirable film deposition taking place there. At least some of the castors of the transport system are therefore placed at a greater distance than in the heating chamber. The structure of the shafts corresponds to that of the transport system shafts in the heating chamber. Since the substrate passes through the deposition chamber having a temperature in the range of the transformation temperature, the shafts are provided with more inner castors and a greater distance of the collars than those shafts for which the substrate temperature is below transformation temperature. In the deposition chamber, a heating system is intended merely above the transport system. Since the temperature of the containers is significantly higher than that of the underside of the substrate, this also results in a heating effect on the underside of the substrate. However, the temperature of the substrate must be markedly lower than the temperature within the containers to result in a deposition of the vaporized or sublimated materials on the substrate's underside. In a preferred embodiment, the temperatures of the substrate's upper and underside are also recorded by sensors in the deposition chamber.

The sensors in the heating and deposition chambers operate preferably contactlessly, and record the temperature on the surface of the substrates preferably due to the emission from the surface (for example pyrometric sensors).

The transfer of the substrate from the transport system of one chamber to that of the following chamber takes place via supply slits, by which means the chambers are connected to each other. Pressure locking takes place only for supplying the substrate to the first chamber, and for removing it from the last chamber.

The conveying shafts of the transport systems are preferably made from fused silica. This material is characterized by very low heat conductivity and high mechanical stiffness, even at high temperatures. The individual castors may be crafted preferably by a process of grinding the—at first cylindrical—shafts by selectively reducing their diameter in areas outside the castors. It is sufficient if the castors project only slightly, preferably by less than 10 mm, over the conveying shaft proper. Owing to the low heat conductivity of the preferably used fused silica the ends of the conveying shafts may advantageously be provided with stainless steel caps on both sides. The conveying shafts are on both sides guided in bearings by means of the stainless steel caps, whereby the drive operates preferably on one side via a gear wheel mechanism. The expansion of a conveying shaft made of fused silica at a high temperature is very limited and may thus be neglected.

Preferably, according to the invention the inner castors are also arranged on the same conveying shaft as the outer castors which are placed in a line crosswise to the transport direction of the substrate. Preferably, the inner castors of the shafts following one another in transport direction are arranged in true alignment. In this case all the castors may be crafted from the conveying shaft. This is done preferably by grinding (abrasion), turning or using another processing method according to the state of the art. However, the goal of smooth running is already essentially attained, if merely the outer casters are mounted on a continuous conveying shaft, so that an arrangement of the inner castors on one or more separate shafts, or a loose bearing guidance of the inner castors on the shaft is also possible, without co-driving the inner castors.

In a preferred embodiment merely some conveying shafts are driven to move the substrate forward while other conveying shafts with the castors arranged on them only serve to support the substrate.

In a suite of alternating heating and deposition chambers, preferably transport systems are used which have only two preferred shaft construction types:
for areas in which the temperature lies near or within the range of the transformation temperature, the shafts are provided with more inner castors and have a greater distance of the collars. The distance of the collars is preferably between 1205 mm and 1207 mm, especially preferably 1206 mm, and the lateral pendulum motion of the substrate disc is thereby advantageously limited to circa ±1 mm.
for areas in which the temperature lies below the transformation temperature, the shafts have a uniform distance of the collars (preferably 1205 mm) and preferably have only one (preferably centred) inner castor. In the range from 25° C. to circa 500° C. the lateral pendulum motion of the substrate disc is limited to ±2.5 mm. The number of inner castors may be higher, if the substrate width requires further support. In this case the number of inner castors increases for shafts in the temperature range above the softening temperature as well.

The use of only two shaft construction types advantageously results in clear cost savings due to the higher number of units produced per construction type.

Due to the fact that the outer castors are arranged on a continuous shaft with a sufficiently high torsional stiffness, the outer castors are always running synchronously, so that slippage caused by a length difference in transmission paths cannot occur any more.

The conical contact areas of the outer castors seen in section preferably have an angle (inclination) of 0.3° to 6°, especially preferably of 0.6° to 4°, and further especially preferably of 1° to 2°. The substrate's movement over the castors is thereby made much smoother and steadier. Preferably the collars of the outer castors have a gradient, which causes a lateral guiding of the substrate without resulting in excessive edge stress, which might lead to damage of the edges. The angle of the collars measured at the section of the shaft is between 120° and 150°, preferably between 130° and 142° and particularly preferably 139°.

In an alternative preferred embodiment of the outer castors no collars are intended; and guiding the substrate in the transport system is effected by lateral guiding castors, which are spring-mounted and create a guiding counter-pressure, if the edge of the substrate deviates laterally from the transport direction.

The device may be used especially advantageously for processing economically-priced soda lime glass, which has a comparatively low softening point. Of course the device may also be used for depositing films on other substrates, for example in the case of glasses which have a higher temperature resistance. It is possible to deposit films on substrates of nearly any desired width, as long as a corresponding number of inner castors is used which are spaced at a suitable distance. Correspondingly, for example glass substrates having a width of 1200 mm and more may also be utilized.

When depositing a film on the preferred lime soda glass substrate having a width of 3.2 mm and at a temperature of circa 550° C., a possible distance between supports of circa 350 mm results. The distance between two castors should therefore be 300 mm to 400 mm, preferably 350 mm. Furthermore, it has been demonstrated that for example a substrate of 1200 mm width resting on two outer castors and one centre castor placed between the outer ones sags to a lesser degree than a substrate of 600 mm width resting on two outer castors only, although in both cases the distance between supports is 600 mm. The reason can be seen in the fact that the bending line of a disc serving as substrate which rests on only two castors acting on the outer edge, intersects the horizontal at a certain angle, whereas the bending line of a disc additionally supported by a central castor must run along the disc steadily, and therefore on grounds of symmetry the angle against the horizontal disappears at the place of the central castor. This advantageous procedure according to the invention allows it to increase the distance between the shafts for the above-mentioned substrate and the process conditions mentioned from the usual circa 230 mm to circa 350 mm.

By decreasing the bending of the substrate the possibility arises to conduct the film deposition at a higher temperature than 520° C., preferably between 540 and 560° C., especially preferably at circa 550° C.

The deposition of CdS/CdTe at a temperature of circa 550° C., when compared to applying lower temperatures, advantageously leads to increased electric efficiency of the completed solar cell. Admittedly, the film deposited on the substrate in the area of the inner castors' track is damaged. In the area of the inner castors, the affected CdS/CdTe layer has a width of <12 mm, and in the area of the outer castors a width of <10 mm. By using further castors only on reaching the transformation temperature, the width of the damaged film area for the additional inner castors is merely circa 6 mm, since in the transformation temperature range the substrate is guided very narrowly as detailed above, and therefore any lateral movement of the substrate is reduced. The damaged areas need to be removed in a later process step. The reduction of the active product surface due to this, however, is more than compensated by the higher process temperature, and the resulting higher electric efficiency. Typically, in a process step following the film deposition, the CdS/CdTe layer in the contact area of the castors is removed again, e.g. by laser ablation. The film may also be removed by sand blasting or mechanical scratching. Alternatively, the damaged layer area may also be separated by two thin insulation cuts, which penetrate the film, but cut only slightly into the substrate. A possible width for insulation cuts of this type is 20 μm to 100 μm. If the photovoltaic quality is only slightly affected by the castors, it may be possible in certain cases to do without any treatment of the contact areas. This is preferably decided at the process step of classifying the substrate. Therefore, a technically and economically sound compromise needs to be found between the desired high process temperature on the one hand and the undesired loss of some surface areas on the other hand.

### Sample Calculation Regarding Size Of Damaged Depositing Area

In the following a sample calculation is presented identifying which damages to depositing the substrate may suffer if the method according to the invention with the device according to the invention is used.

The plate-shaped glass substrate has, for example, a length of 1600 mm, a width of 1200 mm and a thickness of 3.2 mm. The width of the inner castors is preferably 2 mm to 6 mm, particularly preferably 3 mm to 5 mm. A castor width that is as narrow as possible is advantageous, as this keeps the area damaged by the castors, from which the film must be removed later, narrow as well. If the disc is centred, the area damaged by the centre castor is determined by the castor width plus double the guiding tolerance I_{guid,tol} and the dimensional tolerance I_{dim,tol} of the substrate. In order to keep the damaged area small especially in this area, a smaller castor width may be selected for the inner castors, i. e. the centre or intermediate castors, than that of the outer castors.

For example, the inner castor width is 3.0 mm, but the width of the contact areas of the outer castors is 5.0 mm. In this case, assuming a guiding tolerance of the disc of ±0.5 mm and a dimensional tolerance of the disc of von ±0.5 mm, this results in a maximum width of 5 mm of CdTe strip damaged by the inner castors.

If, as already described above, a transformation temperature T_{g} is selected in such a manner that in the range of the transformation temperature a conveying shaft with n_{above} castors, but below the transformation temperature a conveying shaft with n_{below} castors is used, in addition the damage done to the film by the additional castors must be taken into account. At T_{g}=500° C. the linear expansion of the glass substrate between 25° C. and 500° C. dL₂₅₋₅₀₀ amounts to circa 5 mm and the linear expansion between 25° C. and 550° C. dL₂₅₋₅₅₀ to circa 6 mm. The CdTe area damaged by the outer castors thus has a width (b) of

b_{CdTe,outer}b_{castor,outer}+dL₂₅₋₅₀₀/2+2*(I_{guid,tol}+I_{dim,tol})≈9.5 mm

(width of outer castor b_{castor,outer}=5 mm).

The CdTe area damaged by the additional intermediate castors has a width of

b_{CdTe,inter}=b_{castor,inner}+(dL₂₅₋₅₅₀−dL₂₅₋₅₀₀)/4+2*(I_{guid,tol}+I_{dim,tol})≈5.25 mm

(width of inner castor b_{castor,inner}=3 mm).

### Exemplary Embodiment

In the following, an exemplary device is described which is suitable for executing the method according to the invention. The reference numbers refer to the corresponding elements in the figures.

A first heating chamber (3), a deposition chamber (2) and a second heating chamber (3) are arranged after one another.

A plate-shaped substrate (1), made from lime soda glass having a transformation temperature of 550° C. is used. In a previous process step a TCO layer has been already applied as front electrode to the underside of the substrate (1). The width of the substrate (1) in transport direction is 1200 mm at 25° C. The length of the substrate (1) is 1600 mm (at 25° C.). The substrate edge is rounded in a C-cut. The substrate (1) enters the first heating chamber (3) at a temperature of 480° C. It is moved along on a transport system (30). The transport system (30) consists of shafts (31), which have outer castors (313) with angled collars (3132). The inclination of the collar (3132) of each outer castor (313) in a section transecting the shaft axis is 139°. The distance of the collars (3132) is 1205 mm. The substrate rests on the edges, which are in parallel to the transport direction, on the contact areas (3131) of the outer castors (313). The contact areas (3131) have an inclination of 3°, and a width of 10 mm. The substrate (1) is supported in its centre by a first inner castor (314), whose contact area has a width of 3 mm. The substrate (1) is then heated on its upper and underside in the heating chamber (3), and in this process slowly passes through the chamber (at a feed rate of circa 1.5 m/min). From the point where the substrate (1) reaches the range of the transformation temperature, there are two second castors (314) arranged on the shafts (31), again centrally between the first inner castor (314) and the outer castors (313). The distance of the collars (3132) is here 1206 mm. The heating system (34) is now set in such a manner that the substrate (1), on reaching the end of the heating chamber (3) is by 6K hotter on its underside than on its upper side. This temperature difference leads to an inner tension which results in a bulging of the substrate (1) which bulge has its centre point above the substrate (1). Due to the support by three inner castors (314) the bulge cannot form unhindered in downward direction. This results in a stiffening of the substrate (1). Due to this stiffening the substrate (1) passes the shaft distance of 250 mm to the following deposition chamber (2) without bumping into the first shaft (21) of the transport system (20) of the deposition chamber (2). The transport system (20) of the deposition chamber (2) corresponds to the transport system (30) of the heating chamber (3), after reaching the range of the transformation temperature of the substrate (1). The substrate (1) continues to be moved in transport direction. It reaches the first container (10), in which CdS is evaporated at a temperature of 680° C. The substrate (1) is moved over the container (10) at a distance of 5 mm to the edge. The width of the container (10) in transport direction is 300 mm. Since in this area supporting castors cannot be arranged, the substrate (1) bridges this distance merely due to its inner tension and the bulge which results from the temperature difference between upper and underside of the substrate (1). Another factor is that due to the high temperature in the container (10) the underside continues to be heated considerably more than the upper side. The underside of the substrate (1) reaches a temperature of circa 555° C. After passing the first container (10) the substrate is again supported by shafts (21) having two outer castors (213) and three inner castors (214). After three such shafts (21), which are arranged with a distance of 250 mm between them, there follows another container (10) for the material to be deposited with CdS. This and the two following containers (10) for the material to be deposited with CdTe are bridged in the manner described. After this, the coated substrate (1) reaches the second heating chamber (3). Here the substrate is cooled down slowly. The substrate leaves the second heating chamber at a temperature of circa 500° C. Downstream from this second heating chamber, but not described in more detail, there are further heating chambers, in which the temperature of the substrate decreases further. After falling under the transformation range temperature of the glass, the substrate (1) is again conveyed on castors (31), at a distance of the collars (3132) of 1205 mm, and on an only inner castor (314).

### FIGURES

FIG. 1 shows a section through the deposition chamber (2), running vertical to the transport direction. The substrate (1) rests on the outer castors (213) of the shafts (21). Between the outer castors (213) the substrate (1) is supported by the inner castors (214). The shafts (21) are mounted near their ends (211) in shaft bearings (212).

FIG. 2 shows a vertical section through the deposition chamber (2) along the transport direction. The shafts (21) belong to the transport system (20). At the points where the containers (10) with material to be deposited are arranged, the distance of the shafts (21) is markedly greater than in the centre of the deposition chamber (2), where three shafts (21) are arranged spaced apart at a small distance between them.

FIG. 3 shows a 3D view of the deposition chamber (2) with the upper cover of the deposition chamber (2) removed. The upper part of the inner chamber has been removed as well. Between the shafts (21) the containers (10) with material to be deposited are shown. The greater distance (D) of the shafts between the depositing material containers in contrast to the smaller distance (d) between the shafts directly adjoining one another (21) in the centre of the deposition chamber (2) is noticeable. The substrate (1) enters the deposition chamber (2) through the supply slit (22) and is moved through the deposition chamber (2) by means of the conveying shafts (21). Through the second supply slit (22) the substrate (1) leaves the deposition chamber (2) again.

FIG. 4 shows a shaft (21) for the temperature range below the substrate's transformation temperature. Therefore, the shaft (21) has only one inner castor (214) between the outer castors (213). The distance (I) of the collars (2132) of the outer castors (213) is smaller when compared to the shafts (21) near or in the range of the transformation temperature of the substrate (1).

FIG. 5 shows the detail A of FIG. 4 from the shaft (21), in which the shaft end (211) is shown, and the collar (2132) and the contact area (2131) of the outer castor (213) are also shown. The angle (b) of the collars (2132) and the angle, or inclination, (a) of the contact areas is determined, as illustrated, in a section transecting the axis of the shaft (21).

FIG. 6 shows a 3D view of the heating chamber (3) without its upper part. In the heating chamber (3) the shafts (31) are arranged evenly spaced apart. Below the shafts (31) the heating elements (33) are shown. The substrate (1) enters into the heating chamber (3) through the supply slit (32) and is moved by means of the castors (31) through the heating chamber, which it then leaves through the second supply slit (32).

FIG. 7 shows a section through a heating chamber (3) in parallel to the transport direction. The transport system (30) of the heating chamber (3) has the shafts (31). The distance (dd) between the shafts is identical for all neighbouring shafts.

FIG. 8 shows a section through the heating chamber (3) vertical to the transport direction. The shafts (31) each have one inner castor (314) between two outer castors (313). The shafts are mounted outside the inner chamber (35) at their ends (311). The lower reflecting surface (331) and the upper reflecting surface (341), which reflect the heat emitted from the heating system in the direction of the substrate are shown. It may be seen that the reflecting surfaces extend down to cover the sides, to be able to reach the lateral edge of the substrate (1).

FIG. 9 shows the viscosity behaviour of a glass substrate as a function of the temperature. The transformation temperature (553° C.), at which a viscosity exponent of 12.0 is reached, may be gathered from this.

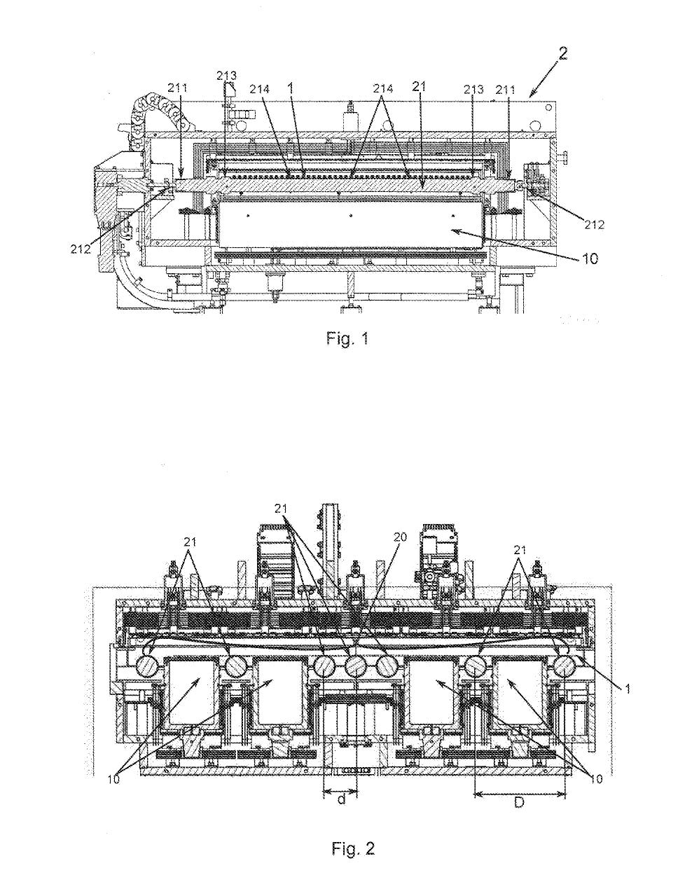

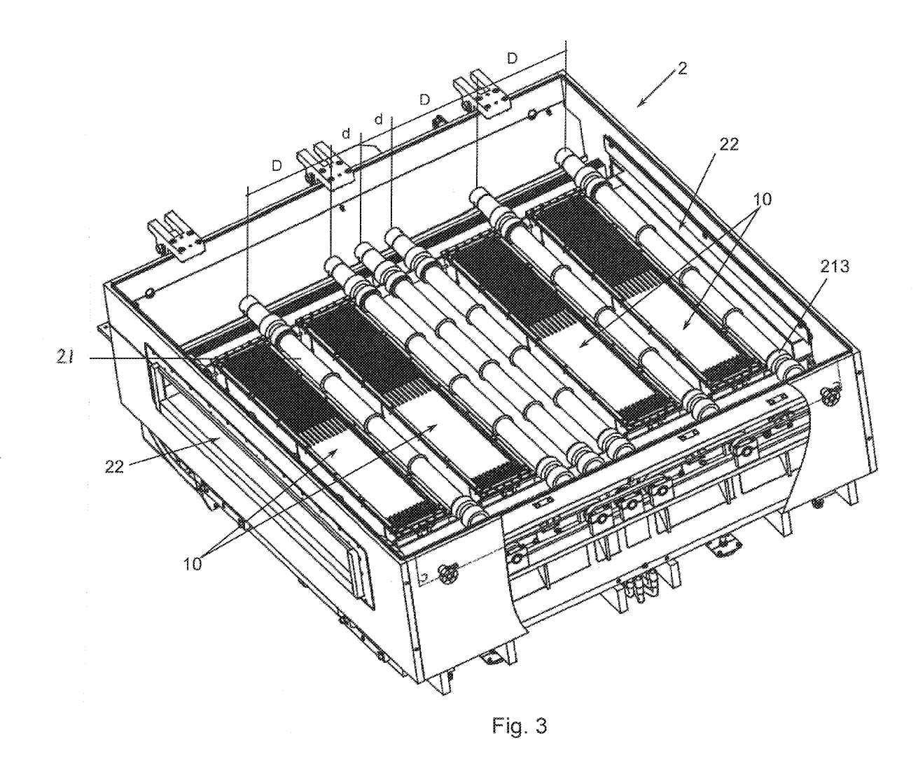

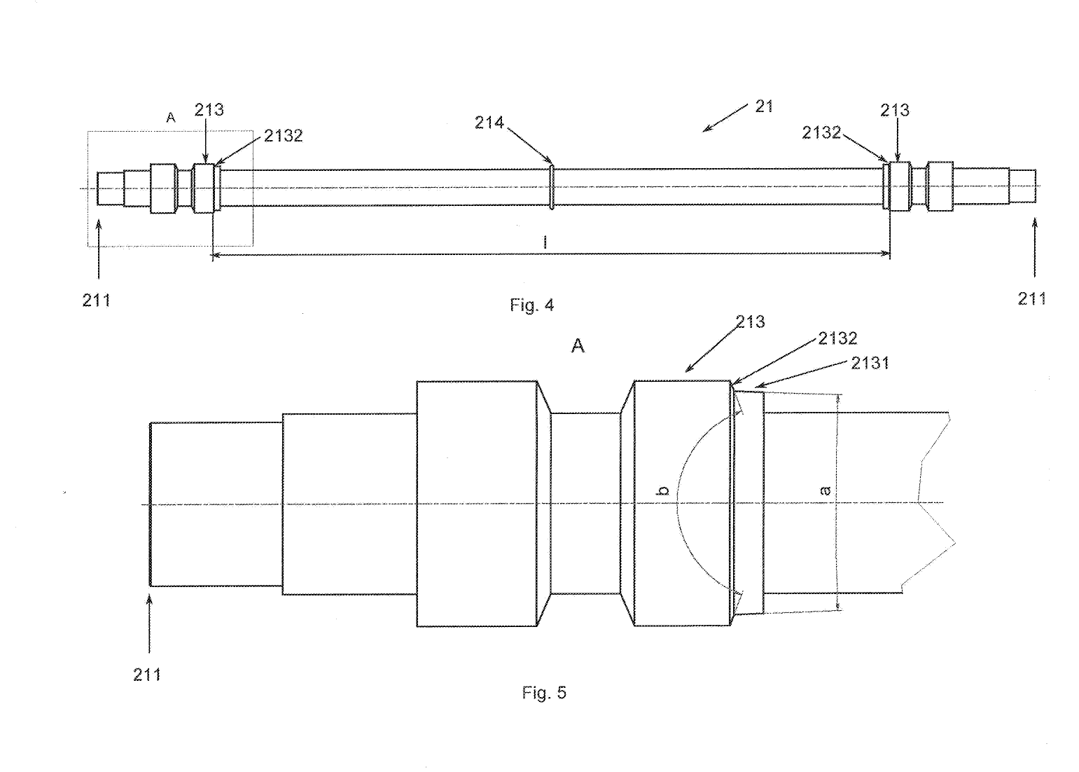

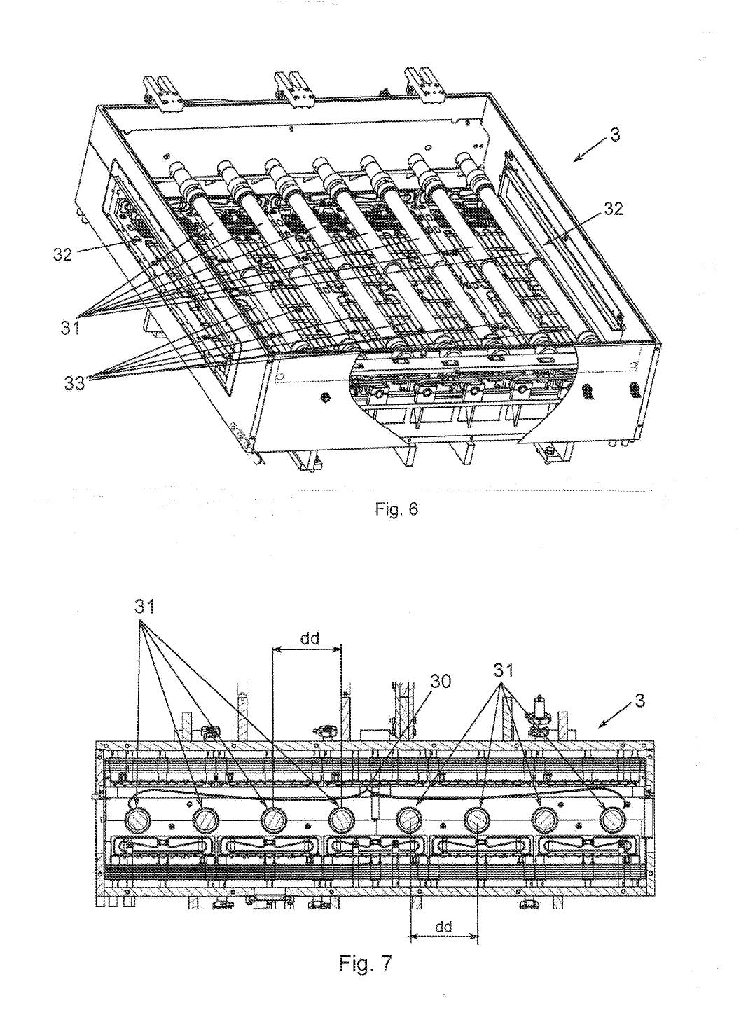

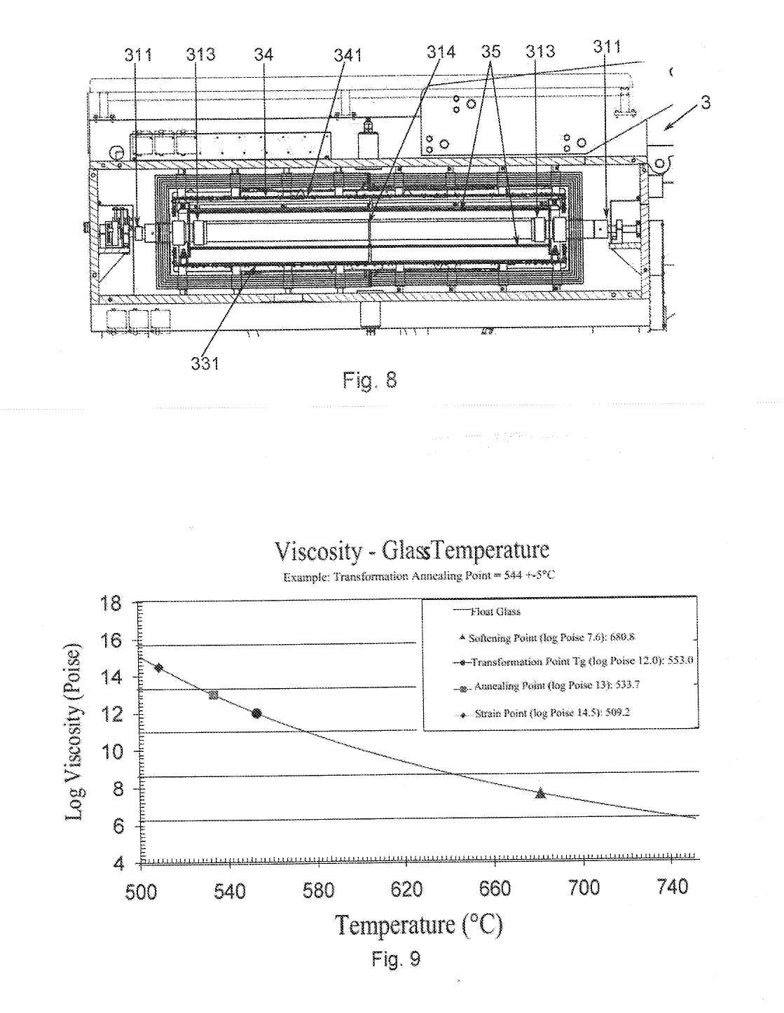

### LIST OF REFERENCE NUMBERS

1 substrate

2 deposition chamber

3 heating chamber

10 container with CdS or CdTe

20 transport system of the deposition chamber

21 shafts of the transport system of the deposition chamber

211 shaft ends of the shafts of the transport system of the deposition chamber

212 shaft bearing of the shafts of the transport system of the deposition chamber

213 outer castors of the shafts of the transport system of the deposition chamber

2131 conical contact areas of the outer castors of the shafts in the deposition chamber

2132 angled collars of the outer castors of the shafts in the deposition chamber

214 inner castors of the shafts of the transport system of the deposition chamber

22 Supply slits of the deposition chamber

30 transport system in the heating chamber

31 shafts of the transport system in the heating chamber

311 shaft ends of the shafts of the transport system of the heating chamber

312 shaft bearing of the shafts of the transport system of the heating chamber

3131 conical contact areas of the outer castors of the shafts in the heating chamber

3132 collars of outer castors of the shafts in the heating chamber

313 outer castors of the shafts of the transport system of the heating chamber

314 inner castors of the shafts of the transport system of the heating chamber

32 supply slit of the deposition chamber

33 heating elements of the heating system in the heating chamber for the underside of the substrate

331 reflecting surfaces of the heating system of the underside

34 heating elements of the heating system in the heating chamber for the upper side of the substrate

341 reflecting surfaces of the heating system of the upper side

35 inner chamber of the heating chamber

i distance of the collars

a angles (i.e. inclination) of the contact area of the outer castors

b angles of the collars

d distance of the shafts in those areas of the deposition chamber where no containers are arranged

dd distance of the shafts in the heating chamber

D distance of the shafts in those areas of the deposition chamber where containers are arranged

What is claimed is:

1-28. (canceled)

29. A method for coating plate-shaped substrates, comprising the steps:
a) heating the substrate to a transformation temperature,
b) simultaneously with and/or subsequent to a): heating the underside of the substrate to a higher temperature than the upper side of the substrate,
c) vapour deposition of at least one material to be deposited on the substrate.

30. The method according to claim 29, comprising lowering the substrate temperature after step c) below the transformation temperature and subsequently repeating steps a) to c).

31. The method according to claim 29, wherein a substrate is used having a transformation temperature between 540° C. and 570° C.

32. The method according to claim 31, wherein the substrate is a lime soda glass.

33. The method according to claim 32, wherein the temperature on the underside of the substrate during deposition is higher than 520° C.

34. The method according to claim 29, wherein the underside of the substrate after step b) has a temperature which is higher than that of the upper side of the substrate by at least 2K to 4K.

35. The method according to claim 29, wherein the materials to be deposited are selected from the group consisting of CdS; CdTe; CdS and CdTe; CIS (copper, indium, selenium); and CIGS (copper, indium, gallium, selenium).

36. The method according to claim 29, wherein the materials to be deposited are CZTS (copper, zinc, tin, sulphur).

37. A device for performing the method according to claim 29, the device comprising:
at least one heating chamber embodied as a vacuum chamber, the at least one heating chamber having heating systems controlled or regulated independently of each other in an inner chamber, wherein a first one of the heating system heats the upper side of the substrate and a second one of the heating systems heats the underside of the substrate, wherein the heating systems are set to heat the substrate so that the underside of the substrate has a higher temperature than the upper side of the substrate,
at least one deposition chamber embodied as a vacuum chamber and positioned downstream, in a transport direction of the substrate, of the at least one heating chamber, the deposition chamber having at least one heatable vaporization crucible with material to be deposited,
a first transport system for the substrate, the first transport system extending through the at least one heating chamber, and a second transport system for the substrate, the second transports system extending through the at least one deposition chamber, wherein the first and second transport systems have several, parallel, axially spaced apart shafts arranged after one another in the transport direction of the substrate, and perpendicular to the transport direction of the substrate, wherein each shaft has outer castors and at least one inner castor, wherein the at least one inner castor is arranged between the outer castors, respectively.

38. The device according to claim 37, wherein the at least one heating chamber has an entrance and an exit for the substrate, wherein the substrate is moved through the entrance without a locking process from an upstream chamber into the at least one heating chamber and is moved out of the at least one heating chamber without a locking process into a downstream chamber.

39. The device according to claim 37, wherein the at least one deposition chamber has an entrance and an exit for the substrate, wherein the substrate is moved through the entrance without a locking process from an upstream chamber into the at least one deposition chamber and is moved out of the at least one deposition chamber without a locking process into a downstream chamber.

40. The device according to claim 37, wherein the outer castors have conical contact areas for the substrate and the conical contact areas have a diameter increasing toward a nearest shaft end of the shaft, wherein the contact areas have an inclination angle of 1° to 5°.

41. The device according to claim 40, wherein the outer castors have angled collars with an inclination angle of 130° to 150° and the angled collars project past the contact areas of the outer castors by at least 5 mm.

42. The device according to claim 41, wherein a distance between the collars of the shafts where the temperature on the underside of the substrate is in the range of the transformation temperature of the substrate is greater than a distance between the collars of the shafts where the temperature on the underside of the substrate is below the transformation temperature.

43. The device according to claim 37, wherein the shafts where the temperature on the underside of the substrate is in the range of the transformation temperature of the substrate have more inner castors than the shafts where the temperature on the underside of the substrate is below the transformation temperature.

44. The device according to claim 37, wherein the inner castors of the transport system, viewed in the transport direction, are arranged in true alignment.

45. The device according to claim 37, wherein a radius of the outer contour of the at least one inner castor at a contact point of the substrate is in the range of 1 mm to 4 mm and a width of the inner castors is 2 mm to 6 mm.

46. The device according to claim 45, wherein a width of contact areas of the outer castors is 6 mm to 12 mm.

47. The device according to claim 37, comprising a drive acting on the shafts in the vacuum chambers, wherein the drive is operatively connected to at least one end of each one of the shafts by a direct mechanical connection.

48. The device according to claim 37, wherein the heating systems of the heating chamber are heating coils arranged as loops, meanders or zigzags, wherein the second heating system for the underside of the substrate is arranged below the shafts.
